(19) United States
(12) Patent Application Publication
(10) Pub. No.: US 2022/0155382 A1
(43) Pub. Date: May 19, 2022

(54) BATTERY MONITORING DEVICE, METHOD, PROGRAM, AND VEHICLE

(71) Applicant: TOYOTA JIDOSHA KABUSHIKI KAISHA, Toyota-shi (JP)

(72) Inventors: Kohei TAKAHASHI, Toyota-shi (JP); Sunao HORITAKE, Toyota-shi (JP)

(73) Assignee: TOYOTA JIDOSHA KABUSHIKI KAISHA, Toyota-shi (JP)

(21) Appl. No.: 17/480,609

(22) Filed: Sep. 21, 2021

(30) Foreign Application Priority Data
Nov. 19, 2020 (JP) 2020-192447

(51) Int. Cl. G01R 31/396; B60L 58/19; B60L 58/22; H01M 10/48; H01M 50/204; H02J 7/00; G01R 31/3842

(52) U.S. Cl. CPC G01R 31/396; B60L 58/19; B60L 58/22; G01R 31/3842; H01M 50/204; H02J 7/0048; H01M 10/482

(57) ABSTRACT

A battery monitoring device monitoring a battery includes an acquisition unit configured to acquire a physical quantity indicating a state of the battery, a decision unit configured to decide whether the battery is in a first state based on the physical quantity acquired by the acquisition unit, and a controller configured to control switching of a relay provided between the battery and a predetermined device connected to the battery and transition between a first mode in which the decision by the decision unit is performed and a second mode in which the decision by the decision unit is not performed as a control mode of the battery. The controller is configured to, when the decision unit decides that the battery is in the first state in the first mode, prohibit transition from the first mode to the second mode and control the relay to a non-conductive state.

### CROSS-REFERENCE TO RELATED APPLICATION

This application claims priority to Japanese Patent Application No. 2020-192447 filed on Nov. 19, 2020, incorporated herein by reference in its entirety.

### BACKGROUND

### 1. Technical Field

The present disclosure relates to a battery monitoring device that monitors a battery mounted on a vehicle and the like.

### 2. Description of Related Art

Japanese Unexamined Patent Application Publication No. 2019-118204 (JP 2019-118204 A) discloses a battery management device that appropriately manages a battery mounted on a vehicle while suppressing power consumption. The management device disclosed in JP 2019-118204 A appropriately manages the battery by using, in addition to switching between a normal mode in which the battery can be managed with high accuracy and a sleep mode in which the accuracy is lowered but power consumption can be reduced, a deep sleep mode in which a relay connecting the battery and an in-vehicle device to each other is brought into a non-conductive state (OFF) to completely separate the battery from the in-vehicle device.

### SUMMARY

Note that, in the normal mode and the sleep mode in the management device disclosed in JP 2019-118204 A, the relay is brought into a conductive state (ON) in order to supply electric power from the battery to the in-vehicle device. Therefore, for example, in a case where an external charger is connected to the battery, when a charging current from the external charger continues to flow excessively into the battery, there is a concern that the battery is overcharged.

The present disclosure provides a battery monitoring device and the like capable of preventing a battery from being overcharged.

A first aspect of the present disclosure relates to a battery monitoring device that monitors a battery. The battery monitoring device includes an acquisition unit, a decision unit, and a controller. The acquisition unit is configured to acquire a physical quantity indicating a state of the battery. The decision unit is configured to decide whether or not the battery is in a first state based on the physical quantity acquired by the acquisition unit. The controller is configured to control switching of a relay provided between the battery and a predetermined device connected to the battery and transition between a first mode in which the decision by the decision unit is performed and a second mode in which the decision by the decision unit is not performed as a control mode of the battery. The controller is configured to, in a case where the decision unit decides that the battery is in the first state in the first mode, prohibit transition from the first mode to the second mode.

A second aspect of the present disclosure relates to a battery monitoring method executed by a computer of a battery monitoring device that monitors a battery or a battery monitoring program. The battery monitoring method includes a step of acquiring a physical quantity indicating a state of the battery, a step of deciding whether or not the battery is in a first state based on the physical quantity acquired in the acquisition step, a step of controlling transition between a first mode in which the decision by the decision step is performed and a second mode in which the decision by the decision step is not performed as a control mode of the battery, and a step of, in a case where decision is made in the decision step that the battery is in the first state in the first mode, prohibiting transition from the first mode to the second mode. The battery monitoring program causes a computer of a battery monitoring device to execute the above steps.

With the battery monitoring device of the present disclosure, it is possible to prevent the battery from being overcharged.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a functional block diagram of a battery monitoring device according to an embodiment and a peripheral portion thereof;

FIG. 2A is a flowchart showing a processing procedure of a mode control executed by a battery controller;

FIG. 2B is a flowchart showing a processing procedure of a mode control executed by the battery controller;

FIG. 3 is a timing chart illustrating a control 1;

FIG. 4 is a timing chart illustrating a control pattern 2;

FIG. 5 is a timing chart illustrating a control pattern 3; and

FIG. 6 is a timing chart illustrating a control pattern of the related art.

### DETAILED DESCRIPTION OF EMBODIMENTS

In a battery monitoring device of the present disclosure, in a case where an external charger or the like is connected to a battery and a current flows into the battery, which causes a concern that the battery is overcharged in the future, the battery is disconnected from the external charger to prevent a state of charge of the battery from increasing further. With this, a fail-safe mechanism that can avoid overcharging of the battery is realized.

Hereinafter, an embodiment of the present disclosure will be described in detail with reference to the drawings.

### Embodiment

Configuration

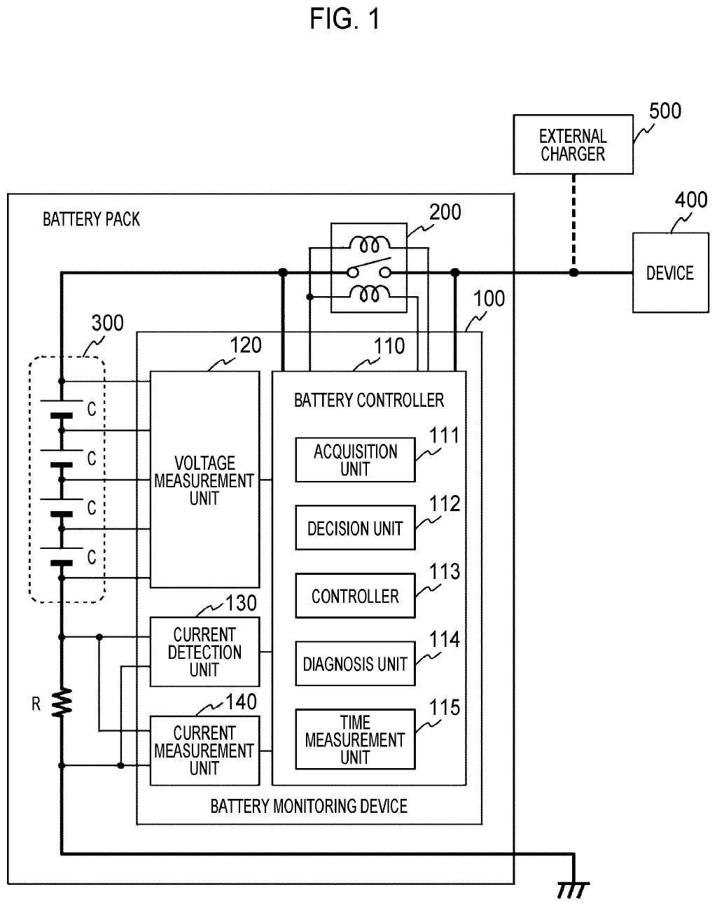

FIG. 1 is a functional block diagram of a battery monitoring device 100 according to the embodiment of the present disclosure and a peripheral portion thereof. The functional block illustrated in FIG. 1 includes a battery pack including the battery monitoring device 100, a relay 200, and a battery 300, a device 400, and an external charger 500. As an example, the battery pack is used in a vehicle, such as an automobile that uses an internal combustion engine as a power source and a hybrid vehicle (HV) that uses an electric motor as a power source.

The battery 300 is a battery that supplies electric power to the device 400 through the relay 200. The battery 300 can be configured by connecting a plurality of cells C of a secondary battery, such as a lithium ion battery configured to be chargeable and dischargeable, in series. The battery 300 can be used as a so-called auxiliary battery that is used for supplying electric power to a device not involved in driving a vehicle. In addition, the battery 300 can be used as a so-called backup sub-battery that is used in an autonomous driving backup power supply system in a vehicle equipped with an autonomous driving function.

The relay 200 is a normally-on-type single-pole single-throw switch. The relay 200 is provided between the battery 300 and the device 400 (and the external charger 500), and based on control (instruction) of the battery monitoring device 100, the connection state of the relay 200 is switched to either a conductive state (ON) in which contacts are electrically connected or a non-conductive state (OFF) in which contacts are electrically disconnected.

The device 400 is a predetermined device connected to the battery 300, and is a device that operates by the electric power supplied from the battery 300 through the relay 200. In a case where the battery 300 is used as an auxiliary battery of a vehicle, examples of the device 400 include an actuator, such as a motor and a solenoid, a light, such as a headlamp and a room light, an air-conditioner, such as a heater and a cooler, a steering, a brake, and an electronic control unit (ECU) for autonomous driving or advanced driving assistance.

The external charger 500 is a predetermined device connected to the battery 300, and is a charger for charging the battery 300. The external charger 500 is configured to be detachable by a user of the battery pack or the like. The external charger 500 includes a charger used in a normal time for the purpose of using the device 400, in addition to a charger used in an emergency, such as when the battery goes dead. The external charger 500 can be connected to a power line connecting the relay 200 and the device 400 to each other, and can cause a charging current to flow into the battery 300 through the relay 200. A part of the charging current is supplied to the battery monitoring device 100 for power supply and also provided for consumption of the device 400.

The battery monitoring device 100 monitors and controls the state of the battery 300 and controls the connection state of the relay 200. The battery monitoring device 100 includes a battery controller 110 including an acquisition unit 111, a decision unit 112, a controller 113, a diagnosis unit 114, and a time measurement unit 115, a voltage measurement unit 120, a current detection unit 130, and a current measurement unit 140.

The acquisition unit 111 acquires a voltage and a current as physical quantities indicating the state of the battery 300 from the voltage measurement unit 120 and the current measurement unit 140. The acquisition unit 111 may acquire a temperature as a physical quantity indicating the state of the battery 300 from the voltage measurement unit 120, the current measurement unit 140, or another configuration. In addition, the acquisition unit 111 derives and acquires a state of charge (SOC) of the battery 300 based on the physical quantities indicating the state of the battery 300. The state of charge (SOC) can be derived based on a well-known SOC-open circuit voltage (OCV) characteristic curve or the like. The state of charge (SOC) of the battery 300 may be acquired directly from the voltage measurement unit 120, the current measurement unit 140, or another configuration.

The decision unit 112 decides whether or not the battery 300 is in a state (first state) in which there is a concern that the battery 300 is overcharged in the future. In addition, the decision unit 112 decides whether or not the battery 300 is in a state (second state) in which estimation can be made that a chargeable device, such as the external charger 500, is connected to the battery 300. Specifically, the decision unit 112 determines whether or not the charging current that flows into the battery 300, the voltage of the battery 300, and the state of charge (SOC) of the battery 300 acquired by the acquisition unit 111 are equal to or greater than predetermined threshold values set respectively, thereby deciding whether or not the battery 300 is in a first state or a second state. The threshold value and the decision will be described below.

The controller 113 performs transition between a “monitoring mode (first mode)” in which diagnosis processing is performed by the diagnosis unit 114 and a “non-monitoring mode (second mode)” in which operation of a part of functions of the battery monitoring device 100 is stopped to make power consumption smaller than that in the monitoring mode without performing diagnosis processing by the diagnosis unit 114 as control mode of the battery 300. In the non-monitoring mode, it is limited to being able to respond to a current detection by the current detection unit 130 and a monitoring mode transition request from an external ECU, and as an example, functions of the diagnosis unit 114, the voltage measurement unit 120, and the current measurement unit 140 are stopped. In addition, the controller 113 performs switching between ON (conduction) and OFF (disconnection) as the connection state of the relay 200. The controller 113 controls transition between the monitoring mode and the non-monitoring mode and switching between ON and OFF of the relay 200 based on the state of the battery 300 acquired by the acquisition unit 111, the status of diagnosis processing by the diagnosis unit 114, and the duration of each mode by the time measurement unit 115. The mode control and relay switching control will be described below.

The diagnosis unit 114 diagnoses whether or not an abnormality occurs in the battery 300 based on the physical quantity indicating the state of the battery 300 acquired by the acquisition unit 111. In the present embodiment, the battery 300 is diagnosed when an ignition switch of the vehicle is turned off (IG-OFF). A method for diagnosing the battery 300 is not the main subject of the present application, and thus description thereof is omitted, but a well-known method can be used.

The time measurement unit 115 measures an elapsed time after the transition of the control mode of the battery 300 from the monitoring mode to the non-monitoring mode is performed by the controller 113. The time measurement unit 115 is, for example, a timer.

The voltage measurement unit 120 measures the voltage of the battery 300, more specifically, the voltage of each battery cell C constituting the battery 300 in the monitoring mode. A voltage sensor (not shown) or the like is used for measuring the voltage. The voltage measurement unit 120 may measure the temperature of the battery 300 using a temperature sensor (not shown). The measured voltage (or temperature) is output to the battery controller 110.

In the non-monitoring mode, the current detection unit 130 detects the current of the battery 300, more specifically, a charging current that flows into the battery 300 and is equal to or greater than a predetermined threshold value. A current sensor (not shown) or the like capable of detecting a current flowing through a load R inserted in series with the battery 300 is used for detecting the current. In a case where a charging current that is equal to or greater than a predetermined threshold value is detected, the battery controller 110 is notified of the detection.

In the monitoring mode, the current measurement unit 140 measures the current of the battery 300, specifically, a discharging current that flows out of the battery 300 and a charging current that flows into the battery 300. A current sensor (not shown) or the like capable of detecting a current flowing through the load R inserted in series with the battery 300 is used for measuring the current. The measured current is output to the battery controller 110.

The battery monitoring device 100 described above can typically be configured as an ECU (monitoring ECU or the like) including a processor, a memory, an input and output interface, and the like. The battery monitoring device 100 of the present embodiment realizes all or a part of the functions of the acquisition unit 111, the decision unit 112, the controller 113, and the diagnosis unit 114 described above by reading and executing a program stored in the memory by the processor.

Control

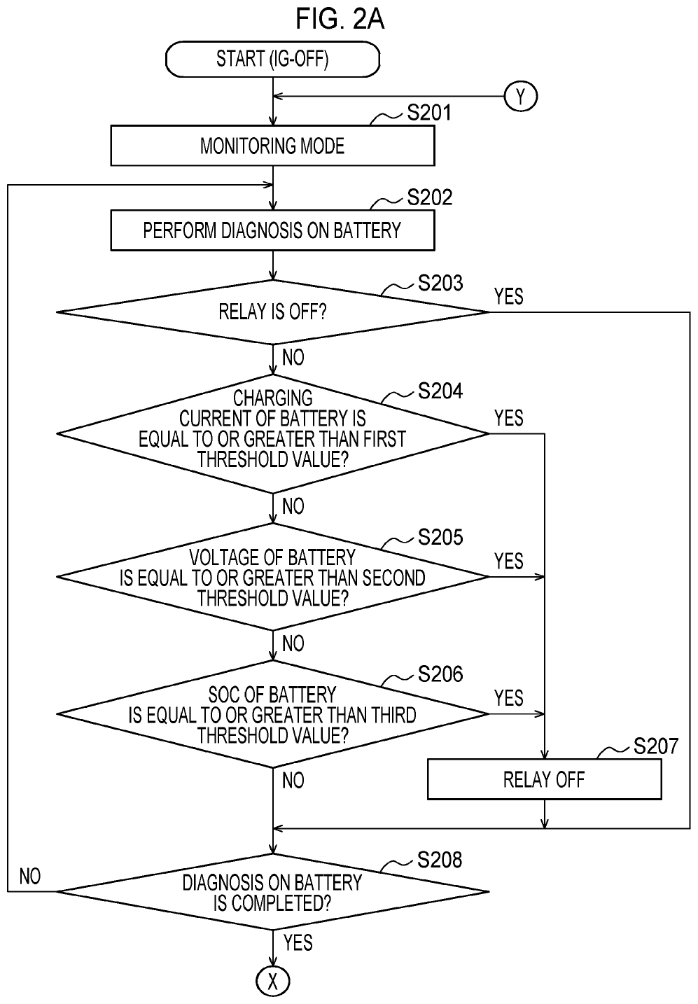

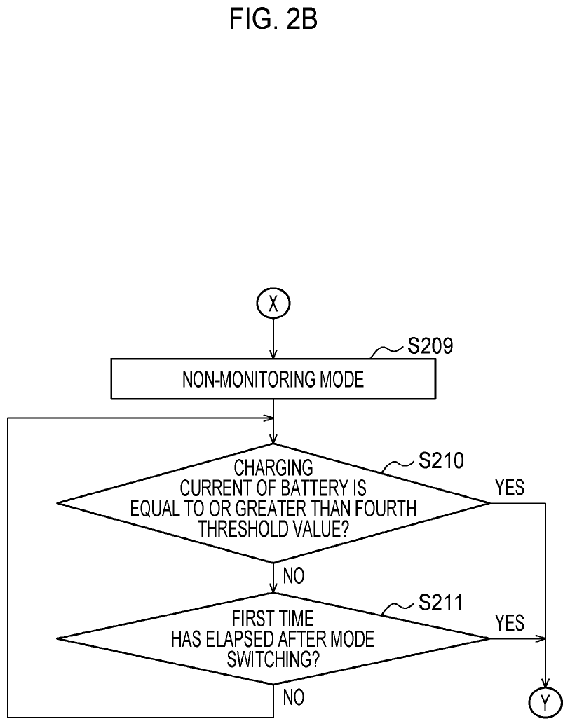

The control performed by the battery controller 110 of the battery monitoring device 100 according to the present embodiment will be described with further reference to FIG. 2A and FIG. 2B. FIG. 2A and FIG. 2B are each a flowchart showing a processing procedure the mode control executed by each configuration of the battery controller 110. Processing of FIG. 2A and processing of FIG. 2B are connected by connectors X and Y.

The mode control shown in FIG. 2A and FIG. 2B is started when the ignition switch of the vehicle is turned off (IG-OFF). The mode control is repeatedly executed until the ignition switch of the vehicle is turned ON (IG-ON), and immediately ends at a time when the ignition switch is turned ON (IG-ON).

Step S201

The controller 113 of the battery controller 110 causes the control mode of the battery 300 by the battery monitoring device 100 to transition to a monitoring mode. That is, in a case where the current control mode is already a monitoring mode, the monitoring mode is maintained, and in a case where the current control mode is a non-monitoring mode, transition from the non-monitoring mode to the monitoring mode is performed. In a case where the transition of the control mode of the battery 300 to the monitoring mode is performed, the process proceeds to Step S202.

Step S202

The diagnosis unit 114 of the battery controller 110 performs predetermined diagnosis processing regarding the battery 300 to be performed in the monitoring mode. In a case where the diagnosis on the battery 300 is performed, the process proceeds to Step S203.

Step S203

The battery controller 110 determines whether or not the connection state of the relay 200 is OFF (disconnection). The connection state of the relay 200 can be determined according to the control state of the controller 113.

In a case where the connection state of the relay 200 is OFF (Step S203, Yes), the process proceeds to Step S208, and in a case where the connection state of the relay 200 is ON (Step S203, No), the process proceeds to Step S204.

Step S204

The decision unit 112 of the battery controller 110 determines whether or not the charging current that flows into the battery 300 acquired by the acquisition unit 111 is equal to or greater than a first threshold value (whether or not the battery 300 is in a first state). The determination is made to decide, based on a current, whether or not there is a concern that the battery 300 is overcharged in the future. In a case where assumption is made that the current continuously flows into the battery 300 from the external charger 500 connected to the battery 300 for a predetermined time, the first threshold value is determined based on a current value estimated to cause the battery 300 at a predetermined state of charge (SOC) to be overcharged. The predetermined time and the predetermined state of charge (SOC) can be appropriately set based on a transition cycle between the monitoring mode and the non-monitoring mode, the capacity and performance of the battery 300, and the like.

In a case where the charging current of the battery 300 is equal to or greater than the first threshold value (Step S204, Yes), the process proceeds to Step S207, and in a case where the charging current of the battery 300 is less than the first threshold value (Step S204, No), the process proceeds to Step S205.

Step S205

The decision unit 112 of the battery controller 110 determines whether or not the voltage of the battery 300 acquired by the acquisition unit 111 is equal to or greater than a second threshold value (whether or not the battery 300 is in a first state). The determination is made to decide, based on a voltage, whether or not there is a concern that the battery 300 is overcharged in the future. In a case where assumption is made that a predetermined current continuously flows into the battery 300 from the external charger 500 connected to the battery 300 for a predetermined time, the second threshold value is determined based on a voltage value estimated to cause the battery 300 at a predetermined state of charge (SOC) to be overcharged. The predetermined current, the predetermined time, and the predetermined state of charge (SOC) can be appropriately set based on a transition cycle between the monitoring mode and the non-monitoring mode, the capacity and performance of the battery 300, and the like. A relationship between the state of charge (SOC) of the battery 300 and the voltage can be acquired based on a well-known SOC-OCV characteristic curve.

In a case where the voltage of the battery 300 is equal to or greater than the second threshold value (Step S205, Yes), the process proceeds to Step S207, and in a case where the voltage of the battery 300 is less than the second threshold value (Step S205, No), the process proceeds to Step S206.

Step S206

The decision unit 112 of the battery controller 110 determines whether or not the state of charge (SOC) of the battery 300 acquired by the acquisition unit 111 is equal to or greater than a third threshold value (whether or not the battery 300 is in a first state). The determination is made to decide, based on a state of charge (SOC), whether or not there is a concern that the battery 300 is overcharged in the future. In a case where assumption is made that a predetermined current continuously flows into the battery 300 from the external charger 500 connected to the battery 300 for a predetermined time, the third threshold value is determined based on a state of charge (SOC) estimated to cause the battery 300 to be overcharged. That is, the third threshold value is set to the state of charge (SOC) at which the battery 300 is likely to be overcharged. The predetermined current and the predetermined time can be appropriately set based on a transition cycle between the monitoring mode and the non-monitoring mode, the capacity and performance of the battery 300, and the like. The state of charge (SOC) of the battery 300 can be obtained from the voltage of the battery 300 based on a well-known SOC-open circuit voltage (OCV) characteristic curve.

In a case where the state of charge (SOC) of the battery 300 is equal to or greater than the third threshold value (Step S206, Yes), the process proceeds to Step S207, and in a case where the state of charge (SOC) of the battery 300 is less than the third threshold value (Step S206, No), the process proceeds to Step S208.

Step S207

The controller 113 of the battery controller 110 switches the connection state of the relay 200 to OFF (disconnection) while maintaining the control mode of the battery 300 by the battery monitoring device 100 in the monitoring mode. That is, while the monitoring mode that is the current control mode is maintained, the connection state of the relay 200 that is currently ON (conduction) is switched from ON to OFF. With this, the battery 300 is disconnected from the device 400, or the battery 300 is disconnected from the device 400 and the external charger 500. In a case where the control mode of the battery 300 is controlled to the monitoring mode and the connection state of the relay 200 is controlled to OFF, the process proceeds to Step S208.

Step S208

The diagnosis unit 114 of the battery controller 110 determines whether or not the diagnosis on the battery 300 is completed. In a case where the diagnosis on the battery 300 is completed (Step S208, Yes), the process proceeds to Step S209 because the monitoring mode can be ended, and in a case where the diagnosis on the battery 300 is not completed (Step S208, No), the process proceeds to Step S202 because the monitoring mode cannot be ended.

Step S209

The controller 113 of the battery controller 110 causes the control mode of the battery 300 by the battery monitoring device 100 to transition from the monitoring mode to a non-monitoring mode. In a case where the transition of the control mode of the battery 300 to the non-monitoring mode is performed, the process proceeds to Step S210.

Step S210

The decision unit 112 of the battery controller HO determines whether or not the charging current that flows into the battery 300 acquired by the acquisition unit 111 is equal to or greater than a fourth threshold value (whether or not the battery 300 is in a second state). The determination is made to decide, based on a current, whether or not the external charger 500 is connected to the battery 300. Therefore, the fourth threshold value is determined based on a current value that may flow from the external charger 500 toward the battery 300 in a case where the external charger 500 is connected to the battery 300. The fourth threshold value may be the same as or different from the first threshold value determined in Step S204.

In a case where the charging current of the battery 300 is equal to or greater than the fourth threshold value (Step S210, Yes), the process proceeds to Step S201, and in a case where the charging current of the battery 300 is less than the fourth threshold value (Step S210, No), the process proceeds to Step S211.

Step S211

The decision unit 112 of the battery controller 110 determines whether or not a first time has elapsed after the transition of the control mode of the battery 300 from the monitoring mode to the non-monitoring mode is performed by the controller 113. That is, the decision unit 112 determines whether or not an elapsed time measured by the time measurement unit 115 is equal to or greater than the first time. The determination is made to avoid an inability to properly diagnose the battery 300 due to long duration of non-monitoring mode. Therefore, the first time is determined based on a suitable cycle for performing the diagnosis on the battery 300.

In a case where the first time has elapsed since the transition to the non-monitoring mode (Step S211, Yes), the process proceeds to Step S201, and in a case where the first time has not elapsed since the transition to the non-monitoring mode (Step S211, No), the process proceeds to Step S210.

In the present embodiment, although a flow in which the process proceeds to Step S207 in a case where any one of the determinations in Steps S204 to S206 is applicable has been illustrated, a flow in which the process proceeds to Step S207 in a case where any two or all three of Steps S204 to S206 are applicable may be used. With such a flow, a determination accuracy is further improved. In addition, as long as lowering of the determination accuracy is acceptable, the flow may be such that solely one or two processes of Steps S204 to S206 are determined.

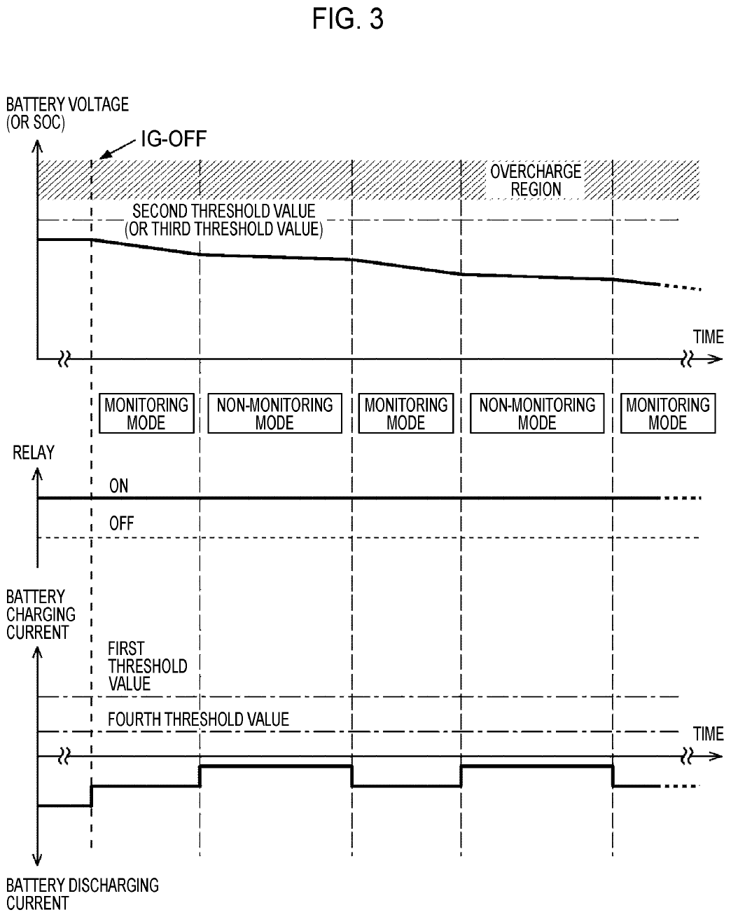

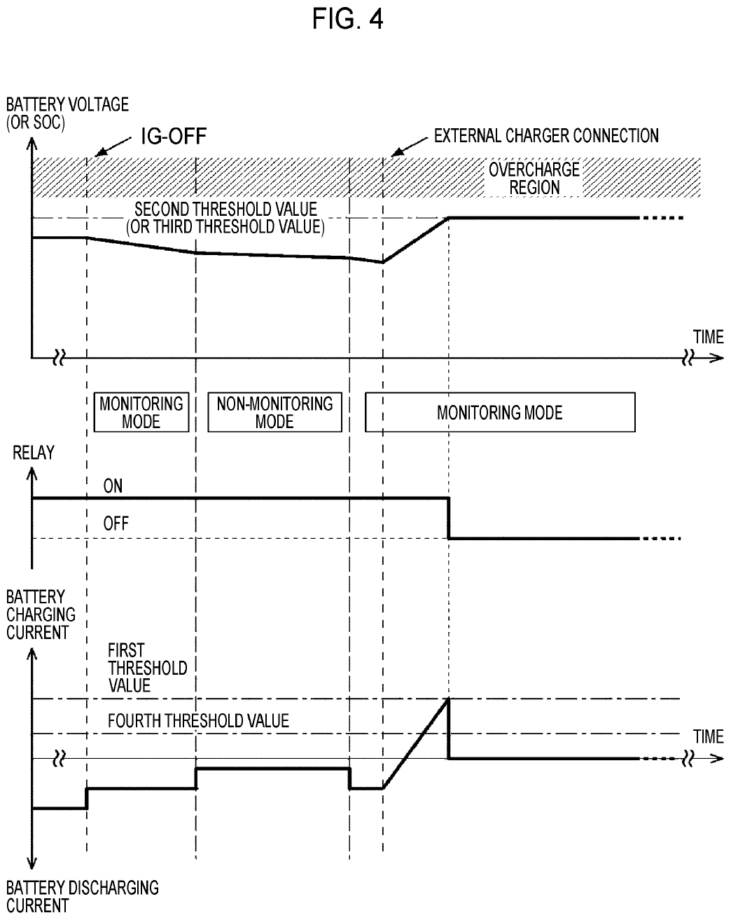

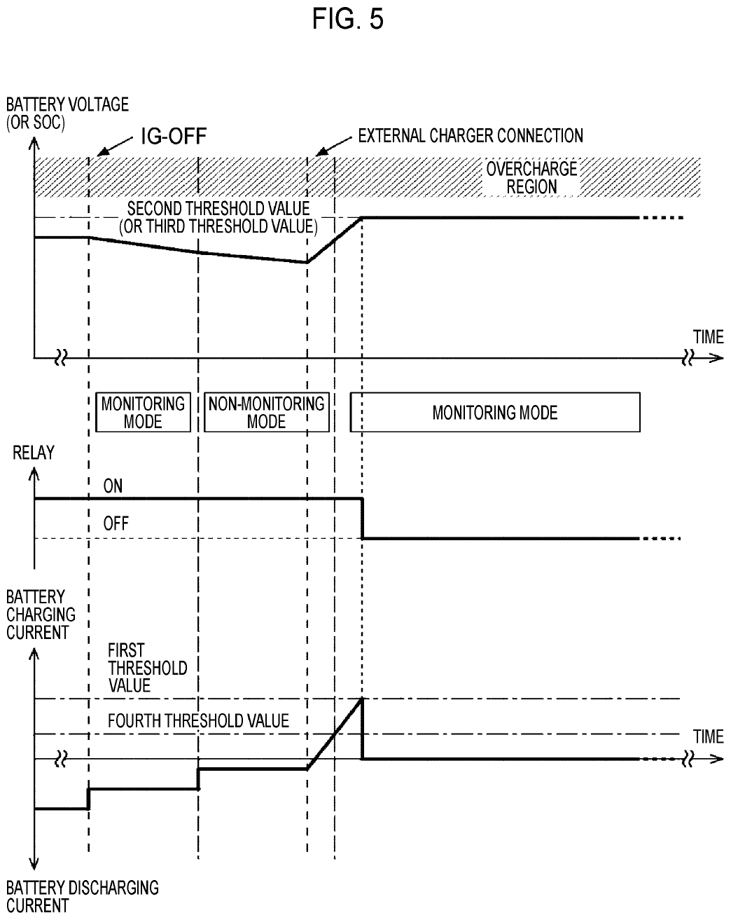

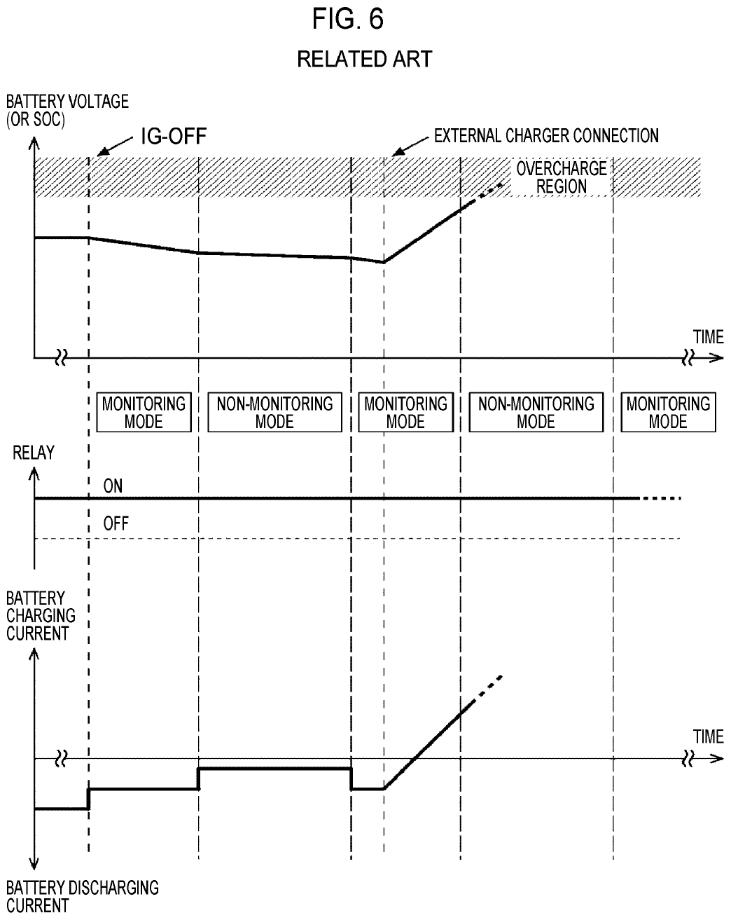

Further, the control performed by the battery controller 110 of the battery monitoring device 100 according to the present embodiment will be described with reference to FIG. 3 to FIG. 6. FIG. 3 is a timing chart illustrating control (control pattern 1) in a case where the external charger 500 is not connected to the battery 300. FIG. 4 is a timing chart illustrating control (control pattern 2) of the present disclosure in a case where the external charger 500 is connected to the battery 300 in the monitoring mode. FIG. 5 is a timing chart illustrating control (control pattern 3) of the present disclosure in a case where the external charger 500 is connected to the battery 300 in the non-monitoring mode. In addition, FIG. 6 is a timing chart illustrating control of the related art (control pattern of the related art) in a case where the external charger 500 is connected to the battery 300 for comparative reference.

Control Pattern 1

In the control pattern 1 shown in FIG. 3, in which the external charger 500 is not connected to the battery 300, after the ignition switch of the vehicle is turned off (IG-OFF), the monitoring mode and the non-monitoring mode are alternately repeated. In the monitoring mode, the voltage (or the state of charge) of the battery 300 drops with a large gradient due to a large discharging current in the diagnosis processing or the like, and in the non-monitoring mode, the voltage (or the state of charge) of the battery 300 drops with a small gradient due to a small discharging current by a partial function stop.

Therefore, in a case of the control pattern 1 in which the external charger 500 is not connected to the battery 300, the battery 300 is not overcharged.

Control Pattern 2

In the control pattern 2 shown in FIG. 4, in which the external charger 500 is connected to the battery 300 in the monitoring mode, the charging current of the battery 300 increases from a time when the external charger 500 is connected (there may be a non-linear increase as well as a linear increase as shown). After that, in a case where the charging current of the battery 300 becomes equal to or greater than the first threshold value, or in a case where the voltage of the battery 300 becomes equal to or greater than the second threshold value or in a case where the state of charge (SOC) of the battery 300 becomes equal to or greater than the third threshold value, the relay 200 is turned OFF to disconnect the charging current that flows from the external charger 500 into the battery 300, and the monitoring mode is maintained (the transition from the monitoring mode to the non-monitoring mode is prohibited). Note that FIG. 4 shows an example in which a timing when the charging current of the battery 300 becomes equal to or greater than the first threshold value and a timing when the voltage of the battery 300 becomes equal to or greater than the second threshold value are the same.

By this control, even in a case where the external charger 500 is connected to the battery 300 in the monitoring mode, the state of charge of the battery 300 can be prevented from increasing further, and overcharging of the battery 300 can be avoided.

Control Pattern 3

In the control pattern 3 shown in FIG. 5, in which the external charger 500 is connected to the battery 300 in the non-monitoring mode, the charging current of the battery 300 increases from a time when the external charger 500 is connected (there may be a non-linear increase as well as a linear increase as shown). After that, in a case where the charging current of the battery 300 becomes equal to or greater than the fourth threshold value, first, the non-monitoring mode transitions to the monitoring mode. Thereafter, as in the control pattern 2, in a case where the charging current of the battery 300 becomes equal to or greater than the first threshold value, or in a case where the voltage of the battery 300 becomes equal to or greater than the second threshold value or in a case where the state of charge (SOC) of the battery 300 becomes equal to or greater than the third threshold value, the relay 200 is turned OFF to disconnect the charging current that flows from the external charger 500 into the battery 300, and the monitoring mode is maintained (the transition from the monitoring mode to the non-monitoring mode is prohibited). Note that FIG. 5 shows an example in which a timing when the charging current of the battery 300 becomes equal to or greater than the first threshold value and a timing when the voltage of the battery 300 becomes equal to or greater than the second threshold value are the same.

By this control, even in a case where the external charger 500 is connected to the battery 300 in the non-monitoring mode, the state of charge of the battery 300 can be prevented from increasing further, and overcharging of the battery 300 can be avoided.

Control Pattern of Related Art

In the control pattern of the related art shown in FIG. 6 for comparative reference, the charging current of the battery 300 increases from a time when the external charger 500 is connected, but the operation is not performed in which the charging current that flows from the external charger 500 into the battery 300 is prevented by turning OFF the relay 200 after detecting that the charging current of the battery 300, or the voltage of the battery 300 or the state of charge (SOC) of the battery 300 becomes equal to or greater than a predetermined threshold value. Therefore, in the control pattern of the related art, there is a concern that the battery 300 is overcharged.

Action and Effect

As described above, in the battery monitoring device 100 according to the embodiment of the present disclosure, determination is made whether or not there is a concern that the battery 300 is overcharged in the future due to an increase of the charging current that flows into the battery 300 in a case where the external charger 500 is connected to the battery 300. When there is a concern that the battery 300 is overcharged in the future, the relay 200 provided in a pre-stage of the battery 300 is turned OFF to disconnect the inflow of the charging current into the battery 300. By this control, the state of charge of the battery 300 can be prevented from increasing further, and overcharging of the battery 300 can be avoided. Therefore, a fail-safe mechanism for overcharge protection of the battery 300 can be realized.

Whether or not there is a concern that the battery 300 is overcharged in the future is determined based on all of the charging current of the battery 300, the voltage of the battery 300, and the state of charge (SOC) of the battery 300, and in a case where any one of the charging current, the voltage, and the SOC is applicable, the inflow of the charging current into the battery 300 is disconnected. By this determination, the overcharge protection of the battery 300 can be quickly executed.

In addition, in the battery monitoring device 100, in a case where there is no concern that the battery 300 is overcharged in the future, the diagnosis processing on the battery 300 can be performed in the monitoring mode, and power consumption of the battery monitoring device 100 can be reduced while electric power is supplied to the device 400 in the non-monitoring mode.

Although the embodiment of the present disclosure has been described above, the present disclosure is not limited to a battery monitoring device, and can also be applied to a battery monitoring method executed by a battery monitoring device including a processor and a memory, a control program of the method, a computer-readable non-transitory storage medium storing the control program, or a vehicle on which the battery monitoring device is mounted.

The present disclosure can be used as a battery monitoring device that monitors a battery mounted on a vehicle.

What is claimed is:

1. A battery monitoring device that monitors a battery, the battery monitoring device comprising:
an acquisition unit configured to acquire a physical quantity indicating a state of the battery;
a decision unit configured to decide whether or not the battery is in a first state based on the physical quantity acquired by the acquisition unit; and
a controller configured to control switching of a relay provided between the battery and a predetermined device connected to the battery and transition between a first mode in which the decision by the decision unit is performed and a second mode in which the decision by the decision unit is not performed as a control mode of the battery,
wherein the controller is configured to, in a case where the decision unit decides that the battery is in the first state in the first mode, prohibit transition from the first mode to the second mode.

2. The battery monitoring device according to claim 1, wherein the first state is a state in which a current that flows into the battery is equal to or greater than a first threshold value, a voltage of the battery is equal to or greater than a second threshold value, or a state of charge of the battery is equal to or greater than a third threshold value.

3. The battery monitoring device according to claim 1, further comprising a diagnosis unit configured to diagnose an abnormality of the battery based on the physical quantity acquired by the acquisition unit,
wherein the controller is configured to, in a case where diagnosis by the diagnosis unit is completed and the decision unit decides that the battery is not in the first state in the first mode, perform switching from the first mode to the second mode.

4. The battery monitoring device according to claim 1, wherein:
the decision unit is configured to further decide whether or not the battery is in a second state based on the physical quantity acquired by the acquisition unit; and
the controller is configured to, in a case where a predetermined time elapses after switching from the first mode to the second mode or in a case where the decision unit decides that the battery is in the second state in the second mode, perform switching from the second mode to the first mode.

5. The battery monitoring device according to claim 4, wherein the second state is a state in which a current that flows into the battery is equal to or greater than a fourth threshold value.

6. The battery monitoring device according to claim 1, wherein the second mode is a mode in which power consumption of the battery monitoring device is smaller than power consumption of the battery monitoring device in the first mode.

7. A battery monitoring method executed by a computer of a battery monitoring device that monitors a battery, the battery monitoring method comprising:
a step of acquiring a physical quantity indicating a state of the battery;
a step of deciding whether or not the battery is in a first state based on the physical quantity acquired in the acquisition step;
a step of controlling transition between a first mode in which the decision by the decision step is performed and a second mode in which the decision by the decision step is not performed as a control mode of the battery; and
a step of, in a case where decision is made in the decision step that the battery is in the first state in the first mode, prohibiting transition from the first mode to the second mode.

8. A battery monitoring program causing a computer of a battery monitoring device that monitors a battery to execute
a step of acquiring a physical quantity indicating a state of the battery,
a step of deciding whether or not the battery is in a first state based on the physical quantity acquired in the acquisition step,
a step of controlling transition between a first mode in which the decision by the decision step is performed and a second mode in which the decision by the decision step is not performed as a control mode of the battery, and
a step of, in a case where decision is made in the decision step that the battery is in the first state in the first mode, prohibiting transition from the first mode to the second mode.

9. A vehicle comprising the battery monitoring device according to claim 1.
